(19) United States
(12) Patent Application Publication
(10) Pub. No.: US 2002/0093356 A1
(43) Pub. Date: Jul. 18, 2002

(54) Intelligent test vector formatting to reduce test vector size and allow encryption thereof for integrated circuit testing

(76) Inventors: Thomas W. Williams, Boulder, CO (US); Rohit Kapur, Cupertino, CA (US); Anthony Taylor, Mountain View, CA (US)

Correspondence Address: WAGNER, MURABITO & HAO LLP, Two North Market Street, Third Floor, San Jose, CA, 95113, US

(21) Appl. No.: 09/728,022

(22) Filed: Nov. 30, 2000

(51) Int. Cl. G01R 31/26

(52) U.S. Cl. 324/765

(57) ABSTRACT

A method and circuit for testing an integrated circuit device using intelligent test vector formatting that reduces the storage required for test patterns and also provides encryption of the test patterns. A first memory stores a test vector mask that is a sequence of bits to indicate if corresponding test vector data is deterministic or random. The test vector data contains a portion that is deterministically generated by automatic test pattern generation (ATPG) software and a portion that is random. A second memory contains a sequence of bits that represent the deterministic test vector data. A random number generator (e.g., linear feed-back shift register, LFSR) generates a reproducible sequence of pseudo random bits that is based on a seed value. A selector circuit is used to select bits either from the second memory or from the random number generator based on the value of the mask vector. The output of the selector provides a fully specified test vector for application to the device under test (DUT). The LFSR can be fabricated on the DUT. The output of the DUT can be coupled back to stages of the LFSR. The bits of the mask vector can readily be compressed thereby saving memory. Neither the first or second memory need to store the random bits because these bits are reproduced on-the-fly by the LFSR, viewed as a compressed data repository. The system provides encryption protection for the test vectors because the LFSR requires the proper seed value before generating the proper sequence of pseudo random bits.

### FIELD OF THE INVENTION

The field of the present invention pertains to the testing of integrated circuits. More particularly, the present invention pertains to a method and system for efficiently storing, applying and encrypting test vectors for use with automated testing equipment (ATE) that test integrated circuits for internal faults.

### BACKGROUND OF THE INVENTION

Computer systems and electronic devices are continually growing in capability and complexity. The size and complexity of integrated electronic systems are likewise increasing, making it critical that the component parts of these systems operate without fault. This requires that each component, or integrated circuit “chip,” be rigorously tested before it is sold. However, as integrated circuit chips become more powerful, the methods and systems required to detect flaws within them become increasingly sophisticated and expensive.

Integrated circuit designs have become more complex in part because they are made more dense. As a result, they have become progressively harder to test in order to ensure correct and complete functionality. Higher densities are achieved in part by reducing the amount of space between transistors and other components which comprise the integrated circuit. As such, the “place and route” tolerances for the integrated circuit are reduced, and the potential for introducing fabrication errors and introducing structural faults in the circuit increases. Additionally, the complicated placement of the internal structure and nature of the defects encountered in such high density integrated circuits requires the use of sophisticated algorithms in order to ensure adequate defect detection, e.g., being able to determine whether structural defects between the closely spaced gate elements, such as a bit short, broken link, or the like, exist. Hence, the testing cost can be very significant for the latest and largest high density integrated circuits.

Very sophisticated test programs, called automatic test pattern generation (ATPG) programs, are used to analyze the integrated circuit designs and generate therefrom test patterns (e.g., also referred to as test programs or test vectors) used for testing the devices in ATE systems. The objective of the ATPG program is to generate an accurate, high defect coverage test pattern as efficiently as possible, to reduce the cost. As a result of analyzing the target design, the ATPG tool determines a stimulus for all the accessible points of the target design. During chip verification, this stimulus is applied by the tester to the integrated circuit and the real time response of the chip is compared with the pre-computed response of the test pattern.

A typical integrated circuit has two categories of faults, commonly referred to as “easy faults” and “hard faults.” Easy faults are categorized as those faults that can be detected by a large number of different test programs, or “test vectors.” Easy faults tend to have relatively few inputs required in order to generate the characteristic output from the integrated circuit which indicates the presence of the fault. Hard faults are characterized as those faults which are detectable by very few test vectors. Hard faults tend to have large numbers of inputs, each of which must be correct, required in order to create a difference in the operation of the good and faulty circuit at an output to indicate the presence of a fault.

Test pattern data is comprised of two portions based upon the way it is computed. The first portion is determined by deterministically traversing the design to provide detection for target faults. The second portion is determined by randomly filling the remaining “don't care” inputs in order to provide for the detection of additional faults that were not targeted by ATPG. The creation of the test pattern and the two phases are depicted by the following example of the evolution of an exemplary test pattern. The starting point of the exemplary 12-position test pattern is that all points are unspecified:

T=x x x x x x x x x x x x

After deterministic analysis on the design, ATPG software generates an intermediate solution which contain deterministic test vector bits and “don't care” positions, x:

T=1 0 1 1 0 x x x x x x x

ATPG's final solution is to complete the test pattern with random values replacing the “don't care” positions:

T=1 0 1 1 0 1 1 0 1 0 0 1

These patterns are stored on the tester and applied to the DUT during test. The expected ratio of deterministic values to random values can be in the range of 1:9. A completely specified test vector is quite difficult to compress in part because it contains random bits. Because some of the input values can also be “don't care” values, X, or high impedance values, Z, two bits are required to store each test pattern input value, e.g., 0, 1, X, and Z need to be represented for each input value. Therefore, prior art testing methods that utilize deterministic test data require 2 n bits of storage for a test pattern having n input values.

Using deterministic test vector data is advantageous because fewer patterns are required to test the integrated circuit, over random patterns. However, deterministic test data is difficult to generate and test patterns having deterministic and random values are difficult to compress. Moreover, prior art testers that use deterministic test data require that all test patterns be stored on the tester and then applied to the device under test (DUT). As a result, prior art testers that use deterministic test data are very expensive.

Other testing methods, called Built-In Self Test (BIST), have applied some test circuitry on the DUT itself. However, BIST has focused primarily on placing random bit generators on the DUT and exclusively used for creating the entire test pattern—which is random or weighted random in nature. An advantage of BIST is that less expensive testers can be used because the testing engine is placed on the DUT. This is one of the reasons why BIST techniques have gained some popularity in recent years. However, a disadvantage of BIST is that it requires many more test patterns to achieve adequate fault coverage because random patterns are used, rather than deterministic patterns. More patterns means longer test periods which increase test cost. Also, by using only random patterns, rather than deterministic data, BIST does not guarantee that all faults can be tested.

It would be advantageous, then, to provide a testing system that offers the advantages of testing with deterministic test data but also leverages the benefits of BIST with respect to its compatibility with less expensive testers. Additionally, often the test patterns generated for a design are given to an outside organization hired to fabricate and test the chip. Unauthorized designers may obtain clues about a circuit's performance or design based on its test patterns. Therefore, it would be advantageous to provide a testing system in which a circuit design could not be discovered based on an inspection of the testing patterns provided for the tester.

### SUMMARY OF THE INVENTION

Accordingly, the present invention provides a testing solution that reduces the overall cost of testing which includes costs associated with the tester and costs associated with the test circuitry on silicon. With the ability to implement millions of gates on a chip, the incremental cost of Design for Test (DFT) is relatively small. The present invention leverages the relatively inexpensive silicon to reduce the cost of the testers by moving some of the tester functionality onto the DUT itself but, unlike BIST, maintain use of deterministic test data. The present invention advantageously reduces the memory required to store fully specified test patterns.

A method and circuit are described herein for testing an integrated circuit device using intelligent test vector formatting that reduces the memory required to store test patterns and also provides an encryption vehicle for the test patterns. The novel circuit includes a first memory that stores a test vector mask. The test vector mask is a sequence of bits that indicates if corresponding test vector data is deterministic or random. The test vector data used by the present invention contains a portion that is deterministically generated by automatic test pattern generation (ATPG) software and a portion that is random. A first data value of the mask indicates deterministic data and a second data value of the mask indicates random data. A second memory contains a sequence of bits that represent the deterministic test vector data. The first and second memory could be separate locations of the same memory device. Alternative variations of this method prefix the positions of deterministic data and random data such that the mask information is minimized to represent the encoded positions.

A random number generator (e.g., linear feed-back shift register, LFSR) is also provided that generates a reproducible sequence of pseudo random bits that is based on a seed value. With respect to encryption, the seed value can be viewed as a key that is required for proper generation of the test vectors. A selector circuit, e.g., a multiplexer, is used to select bits either from the second memory or from the random number generator. The selection is based on the value of a corresponding bit of the mask vector which is coupled to the select input of the selector. The output of the selector provides a fully specified test vector for application to the integrated circuit device under test (DUT). In one embodiment, the circuit can be fabricated in a tester apparatus. However, in a second embodiment, the random number generator can be fabricated on the DUT. In yet another embodiment, the mask memory and the random number generator can be fabricated on the DUT.

It is appreciated that while much of the description herein is devoted to the inputs of the DUT, within another embodiment of the present invention the same technology can be applied to the outputs of the DUT.

In other embodiments, the output of the DUT can be coupled back to an input of the LFSR. Similar to the stimulus on the input side where some inputs were important and were deterministically stored on the tester while the unimportant inputs were obtained from an LFSR, the outputs have important and unimportant values. Outputs at which faults effects are propagated by a test pattern are important and the expected responses can be saved on the tester while all the other expected values can be compared with signatures computed by SISR's (the corresponding LFSR on the output).

Memory is saved because only the deterministic test vector data need be stored in memory. The bits of the mask vector of the output values is sparcely populated with a pointer to deterministic data that it can readily be compressed thereby saving more memory. Memory can also be saved because the input (first) or the output (second) memory to store the random bits are needed, because these bits are generated on-the-fly from the LFSR. The present invention appreciates that with respect to the automation tools, one random set of vectors is as good as another, and therefore allows the LFSR to generate the needed random bits of the test patterns. Although the bits of the LFSR are generated on-the-fly, they are a reproducible (and simulated) sequence based on the seed value provided to the LFSR. The LFSR is representative of the compressed version of the test data and the present invention provides the ability to decompress the test data when instructed to do so by the tester. The LFSR can therefore be viewed as a compressed data repository for the random bits. Embodiments of the system also provide encryption protection for the test pattern because the LFSR requires the proper seed value before generating the proper sequence of pseudo random bits.

More specifically, an embodiment of the present invention includes an integrated circuit tester apparatus comprising a first memory for storing therein a mask vector for characterizing corresponding test vector data, the mask vector comprising a plurality of bit positions wherein a first bit value indicates that the corresponding test vector data is deterministic and wherein a second bit value indicates that the corresponding test vector data is pseudo random; a second memory for storing therein deterministic test vector data; a random number generator for generating a reproducible sequence of pseudo random bits based on a seed number; and a selector circuit for generating a test vector for application to an integrated circuit, the selector circuit for selecting bits as between the random number generator and the second memory based on the mask vector, the selector circuit having an output for coupling to the integrated circuit. Embodiments include the above and wherein the random number generator is a linear feedback shift register. Embodiments include the above and further comprising a decompressor coupled between the first memory and the selector circuit and wherein the deterministic test vector data is generated by an automatic test pattern generator (ATPG) process and downloaded into the second memory.

### BRIEF DESCRIPTION OF THE DRAWINGS

The present invention is illustrated by way of example and not by way of limitation, in the figures of the accompanying drawings and in which like reference numerals refer to similar elements and in which:

FIG. 1 is a diagram of an automatic test equipment (ATE) system upon which embodiments of the present invention can be practiced.

FIG. 2 illustrates a block diagram of one embodiment of the test pattern storage and application circuit of the present invention where the pseudo random number generator is on the tester apparatus.

FIG. 3 illustrates a block diagram of one embodiment of the test pattern storage and application circuit of the present invention where the pseudo random number generator is implemented on the device under test.

FIG. 4A is a circuit diagram of one implementation of the linear feedback shift register used as the pseudo random number generator.

FIG. 4B is a circuit diagram of another implementation of the linear feedback shift register used as the pseudo random number generator.

FIG. 5 shows a block diagram of a general purpose computer system on which automatic test pattern generation processes can be implemented.

FIG. 6A and FIG. 6B are a flow diagram illustrating a process of the present invention in which the circuit of FIG. 2 or the circuit of FIG. 3 can be used to efficiently store, reproduce and apply test patterns to a device under test.

FIG. 7 is a block diagram of a circuit that can be used in accordance with an embodiment of the present invention to efficiently perform test of the outputs of a device under test.

### DETAILED DESCRIPTION OF THE INVENTION

Reference will now be made in detail to the embodiments of the invention, an efficient test pattern storage and generation system, examples of which are illustrated in the accompanying drawings. While the invention will be described in conjunction with the preferred embodiments, it will be understood that they are not intended to limit the invention to these embodiments. The invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well known methods, procedures, components, and circuits have not been described in detail as not to obscure aspects of the present invention unnecessarily.

### Notation and Nomenclature

Some portions of the detailed descriptions which follow are presented in terms of procedures, steps, logic blocks, processing, and other symbolic representations of operations on data bits within a computer memory. These descriptions and representations are the means used by those skilled in the data processing arts to convey most effectively the substance of their work to others skilled in the art. A procedure, computer executed step, logic block, process, etc., are here, and generally, conceived to be self-consistent sequences of steps or instructions leading to a desired result. The steps are those requiring physical manipulations of physical quantities. Usually, though not necessarily, these quantities take the form of electrical or magnetic signals capable of being stored, transferred, combined, compared, and otherwise manipulated in a computer system. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present invention, discussions utilizing terms such as “processing,” “computing,” “simulating,” “translating,” “instantiating,” “determining,” “displaying,” “recognizing,” or the like, sometimes refer to the action and processes of a computer system, or similar electronic computing device, that manipulates and transforms data represented as physical (electronic) quantities within the computer system's registers and memories into other data similarly represented as physical quantities within the computer system registers or memories or other such information storage, transmission, or display devices.

### Automatic Test Equipment (ATE) System

As described more fully below, the embodiments of the present invention provide an efficient system and method for storing the test patterns and for applying the test patterns to the device under test (DUT) 16. By using the systems and methods of the present invention, more of the tester functionality can be placed onto the DUT 16 thereby reducing the complexity and cost of the tester 14. This can be accomplished while also using test vectors that offer the benefits of both deterministic and random portions. In addition, the present invention provides a system for encrypting test patterns to prevent their discovery and use by unauthorized parties.

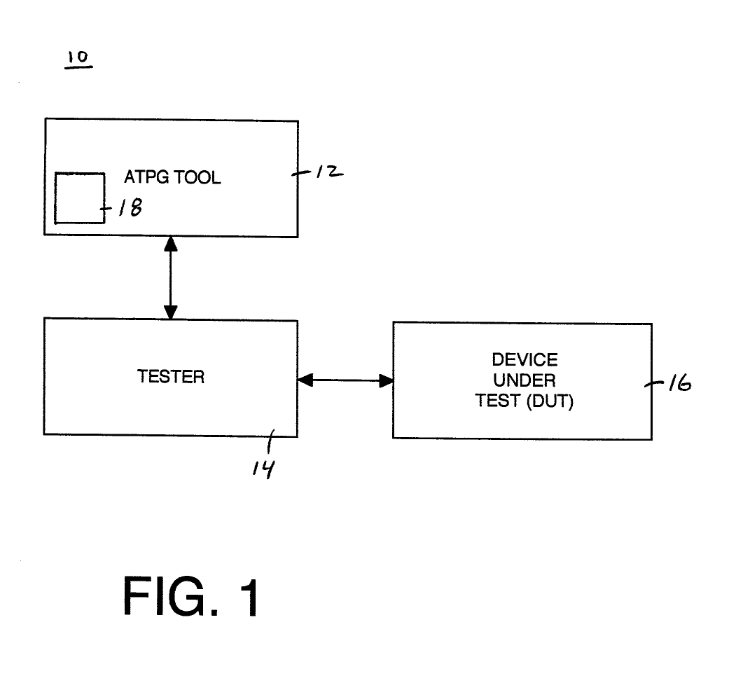

FIG. 1 illustrates a testing system 10 including an ATPG tool 12 coupled to a tester device 14 which is coupled to a DUT 16. The DUT 16 is typically an integrated circuit or “chip.” The ATPG tool 12 is generally described as a computer system that is programmed to execute ATPG processes. The primary purpose of the ATPG system 12 is to efficiently generate test vectors which provide a high degree of coverage for detecting both easy faults and hard faults. To accomplish this, the ATPG tool 12 contains a netlist description 18 of the electronic design that is found within the DUT 16. The netlist 18 can be written in HDL (high level design language) and is used to generate corresponding fabrication components (e.g., lithography masks, etc.) that are used to fabricate the actual device in silicon. Therefore, the DUT 16 is a physical representation of the design within the netlist 18. As examples, the memory cells within the netlist 18 can be edge triggered flip-flops and other types, such as level sensitive modes, e.g., Level Sensitive Scan Design (LSSD) modes, clocked scan modes, clocked LSSD modes, and auxiliary clocked LSSD modes. Not only does the ATPG tool 12 generate test patterns, but during simulation it also captures the expected outputs of the netlist 18 based on the application of these test patterns.

In operation, the ATPG tool 12 examines the netlist 18 and, using well known procedures, generates therefrom a set of test patterns that are used to locate faults within the DUT 16. The test patterns comprise a certain number of data points (D) that are deterministically generated and another number of data points (R) that can be filled with random values. The fully specified test patterns therefore contain (D+R) number of data points. Since a data point can be 1, 0, X (don't care) or Z (high impedance), two bits are generally required to represent each data point in the prior art systems. The ATPG tool 12 informs the tester 14 of the test patterns and the tester 14 applies the test patterns to the DUT 16 and examines the real output of the DUT 16 against the expected output as computed by simulations performed by the ATPG tool 12. In order to accurately test the integrated circuit block of the DUT 16, the tester 14 scans test vectors into memory cells of the DUT 16 during test mode and the DUT 16 is then operated which generates a set of outputs. The tester 16 then recalls the output from the DUT 16. The test vectors provide the necessary inputs in order to detect the presence of faults within the DUT 16.

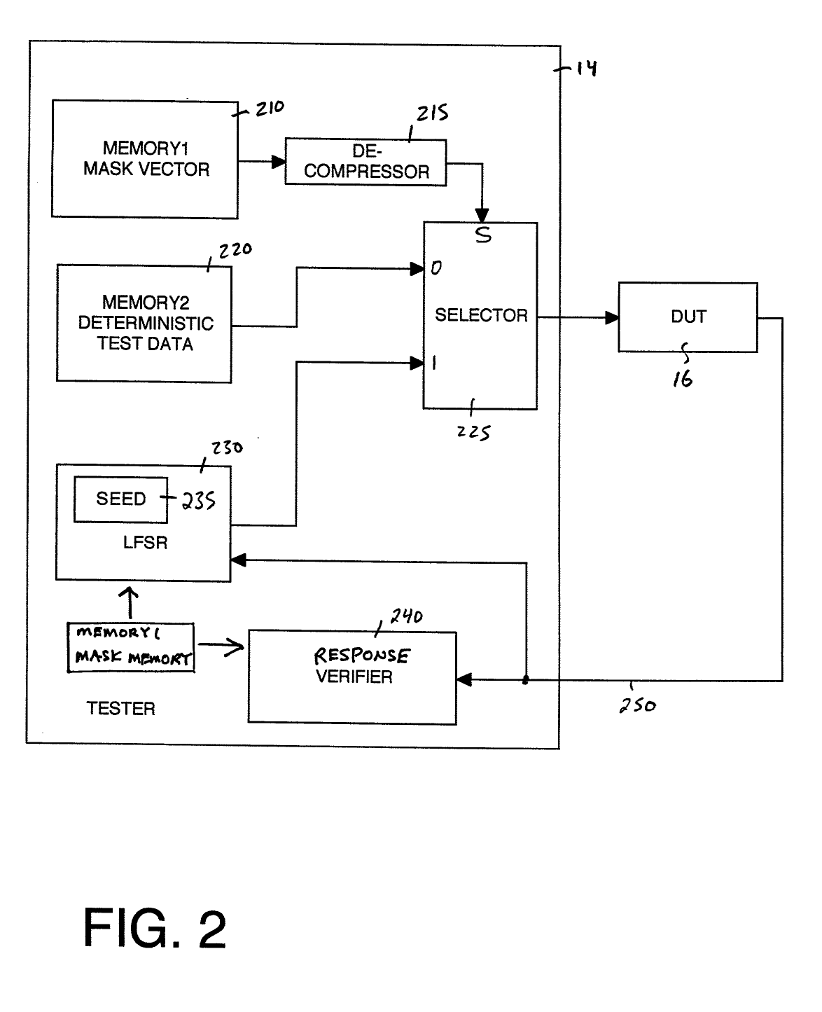

FIG. 2 illustrates a tester 14 in accordance with one embodiment of the present invention. Tester 14 is coupled to DUT 16 using well known multi-pin test access ports. Tester 14 includes a first memory (memory1) 210 for containing a mask vector. The mask vector is generated by the ATPG tool 12 and contains a sequence of bits. The mask vector contains a respective bit for each data point of the test patterns, e.g., the mask vector contains D+R bits (when not compressed). The bits of the mask vector indicate if the corresponding test pattern data point is deterministic or random in its source. In one embodiment, a “0” in the mask vector indicates a deterministic data source and a “1” in the mask vector indicates a random data source. It is appreciated that these logic value assignments can also be reversed. An exemplary uncompressed portion of a mask vector is illustrated below:

mask₁₃ vector={0 0 0 0 1 1 1 1 1 1 . . . }

This indicates that the corresponding test pattern data points include four deterministic data points followed by six randomly generated points. By removing the random data from the stored test pattern and creating a mask vector, as described above, the present invention is readily able to compress the stored mask vector because it is very regular in pattern. It is appreciated that any of a number of well known methods can be used to perform data compression on the stored mask vector. However, compressing the mask vector is optional. If the mask vector is compressed, then a decompressor 215 is required to decompress the mask vector before it is used in accordance with the present invention.

The bits of the mask vector are used to control the select input of a selector circuit 225 of FIG. 2. In one embodiment, the selector circuit 225 can be a multiplexer circuit. A second memory (memory2) 220 contains the deterministic data bits of the computed test pattern. Since deterministic data is either a “1” or a “0,” only one bit is required for representing each deterministic data point. Therefore, for a test pattern having D number of deterministic data points, memory2 220 stores D number of data bits. The output of memory2 220 is coupled to the “0” input of the selector circuit 225. An exemplary sequence of deterministic data is listed below:

deterministic={1 0 1 1 . . . }

The tester 14 of FIG. 2 also uses a compressed data repository for the random bits. A pseudo random number generator circuit 230 in accordance the present invention is used as the compressed data repository. The pseudo random number generator circuit 230 in one embodiment can be a linear feed-back shift register (LFSR) circuit having multiple stages. The LFSR circuit 230 can accept a predetermined seed value 235. Thereafter, each stage of the LFSR circuit 230 will generate a reproducible sequence of pseudo random bits depending on the design of the LFSR 230. The present invention utilizes the pseudo random number generator circuit 230 as a compressed data repository for the random numbers required for the random number data positions of the fully specified test pattern. A random number generator can be used in this capacity because the present invention recognizes that automation tools are equally effective with a one random set of vectors over another. The output of random number generator circuit 230 is coupled to the “1” input of the selector circuit 225. Listed below is an exemplary pseudo random sequence of bits generated by circuit 230 for a particular seed value:

pseudo_random={1 0 1 1 0 1 . . . }

The selector circuit 225 of FIG. 2 therefore selects bits either from memory2 or from the LFSR circuit 230 according to the mask vector information provided to its select input. Based on the exemplary sequences of the mask vector, the deterministic data and the random data, the selector 225 generates the following fully specified test vector (test_vector) as an output:

| | | | | |
|---|---|---|---|---|
| mask_vector = | { | 0000 | 111111 . . . | } |
| deterministic = | { | 1011 . . . | | } |
| pseudo_random = | { | | 101101 . . . | } |
| test_vector = | { | 1011 | 101101 . . . | } |

This test vector is applied by the tester 14 to the DUT 16. The output of the DUT 16 is then feed back to the verifier 240 of the tester 14. The verifier contains the expected output of the DUT 16 based on the simulations performed by the ATPG tool 12 (FIG. 1). If the actual output of line 250 does not match the expected output, then an error flag is set that can be used to reject the DUT 16.

Optionally, the output of the DUT 16 can be fed to stages of the LFSR circuit 230 in order to produce more randomness in the reproducible pseudo random sequence. It is appreciated that in one embodiment, sampling of the circuit 230 for random values is done in such a way that the scan values are obtained by possibly cycling the circuit 230 and the broadside stimulus is preferably obtained without cycling the circuit 230 through different states.

It is appreciated that in one embodiment, the ATPG tool 12 needs to know the sequence of bits generated by the LFSR 230 in order to generate itself the fully specified test patterns. In this embodiment, the fully specified test patterns are needed by the ATPG in order to properly simulate the netlist 18 to obtain the expected results. The seed value 235 makes the sequence of bits generated by the LFSR 230 a reproducible sequence. Therefore, the ATPG tool 12 needs to know the type of LFSR 230 that is used by tester 14 and also its seed value 235. In general, the ATPG determines the seed value and forwards this information to the LFSR.

An advantage of the embodiment of the present invention, as shown in FIG. 2, is that the memory required for storing the test patterns is reduced. Unlike the fully specified test vector, the vector mask of memory1 210 can be compressed thereby reducing the size required of memory1 210. Secondly, the LFSR 230 acts like a pre-specified compressed data repository for the random bits of the test pattern. By doing this, the present invention effectively compresses the random portion of the test patterns. Using the LFSR 230, the random bits (R number of bits) of the test pattern do not need to be stored in memory. Memory2 220 is required only to store the deterministic bits (D number of bits) of the test patterns. Given that the number of random bits (R) typically outnumber the number of the deterministic bits (D) by a ratio of 9:1, the size of memory2 220 can be relatively small. The complete test pattern used by the present invention can be viewed as a combination of a statically stored portion and a dynamically created portion. The mask vector indicates which source is to be used for the selection.

Since the mask vector includes D+R number of bits, the total memory required to store a test pattern having a deterministic part (D) and a random part (R) can be expressed as:

2D+1R

This value is a maximum required value and the largest part of this size, e.g., the mask vector at 1D+1R in size, can significantly be reduced by compression. For example, if the positions of the D-values and R-values are pre-fixed for a set of vectors, mask data can be encoded to imply those positions. Prior art testers require two bits of storage per test data point and they require, minimally, 2D+2R memory storage for the same test vector. Given that the number of random bits (R) typically outnumber the number of the deterministic bits (D) by a ratio of 9:1, the present invention significantly reduces the memory required to store a fully specified test pattern. Although the embodiment of FIG. 2 saves tester memory, it does not significantly reduce the throughput of the data flowing from the tester 14 to the DUT 16.

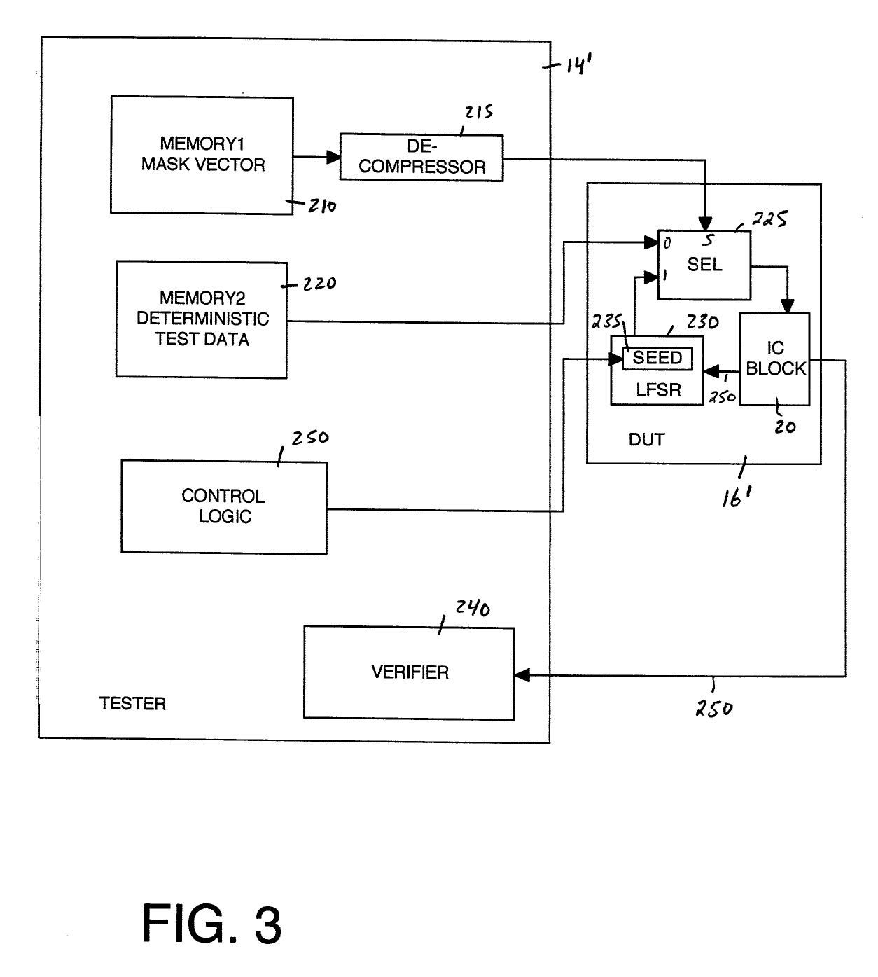

The system of FIG. 3 acts to reduce the throughput of the data flowing from the tester 14′ to the DUT 16′ . The embodiment of FIG. 3 reduces the tester throughput to the DUT 16′ by incorporating the LFSR circuit 230 on the DUT 16′ itself. A configurability mechanism for sending data from the tester 14′ or the compressed data source on the DUT 16′ can be built-in. The control of the source of test data to the design would lie in the hands of the control logic 250 of the tester 14′. The embodiment of FIG. 3 also offers an increase in performance. Specifically, this configuration allows for the possibility of obtaining and applying the data portion that is generated on the DUT 16′ at a faster rate than that could be achieved from a low cost tester.

The system of FIG. 3 is similar to the system of FIG. 2 except that the LFSR circuit 230 and the selector circuit 225 are placed on the DUT 16′. The portion of the DUT 16′ that corresponds to the netlist 18 is the IC block 20. In this configuration, the output of the select circuit 225 is coupled to feed the IC block 20. Unless already programmed on the LFSR, a seed value is sent from the tester 14′ to the LFSR circuit 230 on the DUT 16′. The output of memory1 210, e.g., the mask vector, is also fed to the DUT 16′. Control logic 250 controls the sequencing of bits from memory1, memory2 and from the LFSR 230 for application to IC block 20. It is appreciated that bits from the LFSR 235 can be clocked into the IC block 20 at a much faster rate then the deterministic data from memory2 220. The output 250 of the IC block 20 is fed back to the verifier 240 of the tester 14′ for comparison against the simulated or expected output. As before, the output 250 can also optionally be fed to the LFSR circuit 230.

By removing the circuitry from the tester 14′, and placing it into the DUT 16′, a lower cost tester 14′ can also be realized. By moving this circuitry to the DUT, this embodiment of the present invention leverages the relatively inexpensive silicon to reduce the cost of testers.

As an added function of the system of FIG. 3, an encryption mechanism is also provided. Some providers consider test patterns as secret. If test patterns use the system of FIG. 3, the test patterns are incomplete and thereby partially encrypted without the seed value. The randomly created portion of the test data can only be determined by knowing the details of the LFSR and the seed used to generate the random data. This information can effectively be hidden within the DUT or the seed can be given only as a key. By using the system of FIG. 3, providers have increased control over their test patterns.

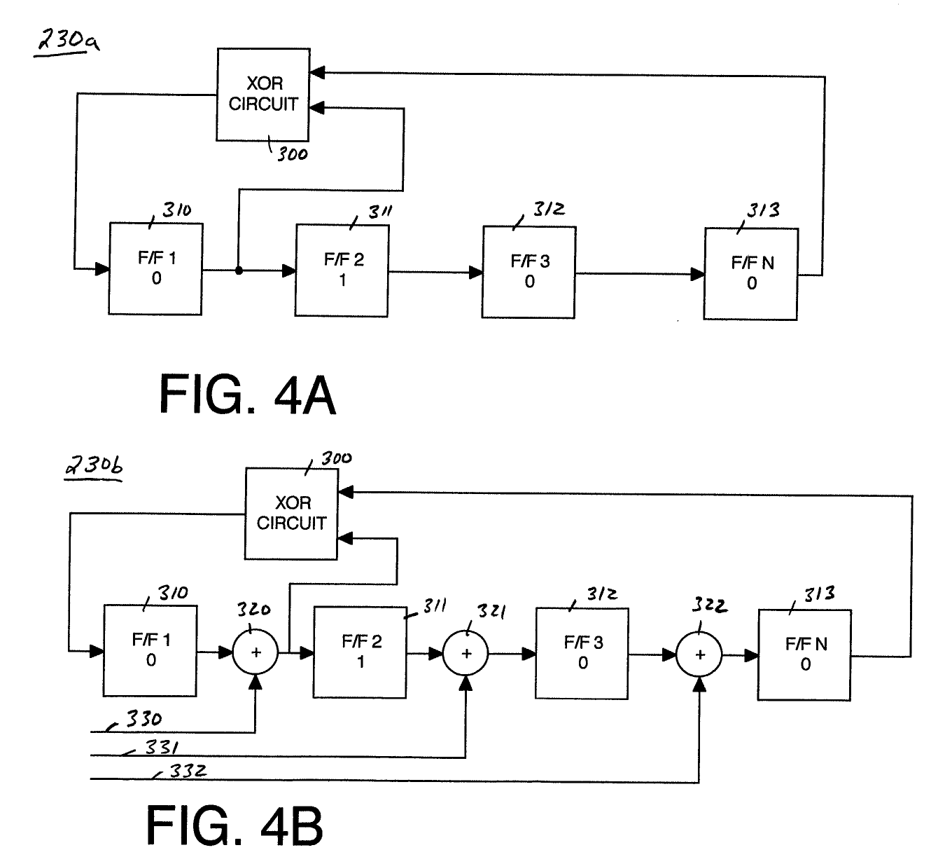

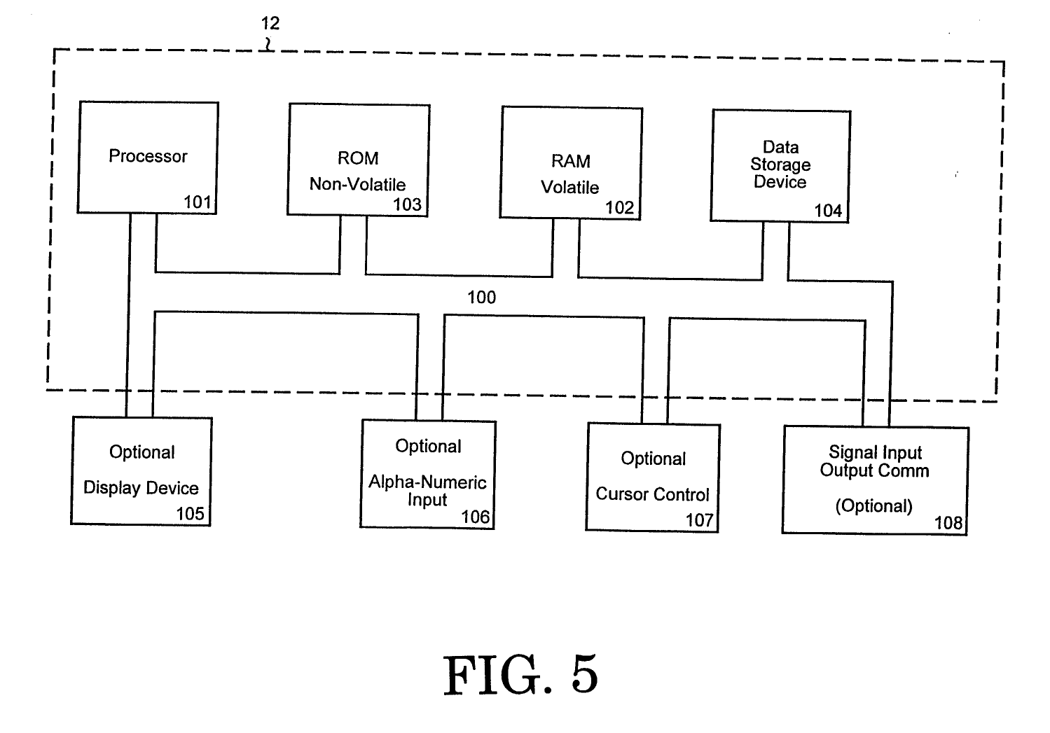

FIG. 4A illustrates one exemplary LFSR circuit 230a that can be used in accordance with the present invention. The LFSR circuit 230a is a multistage circuit, shown here having n flip-flop (F/F) stages. The output of an XOR circuit 300 is fed to the first stage 310 and the output of stage 310 is fed to the input of the second stage 311 and also to the input of the XOR circuit 300. The output of the second stage 311 is fed to an input of the third stage 312. The output of the third stage 312 is fed to an input of the fourth stage 313 and the output of the fourth stage 313 is fed to the other input of the XOR circuit 300. The seed value represents the initial value loaded into each of the F/F stages, e.g., 0 1 0 0. Each of the flip-flops are commonly clocked and when cycled each stage generates a pseudo random sequence of bits that is reproducible given the seed value. It is appreciated that the output of the LFSR 230a can be taken from any of the stages. It is appreciated that any number of stages can be used in accordance with this embodiment of the present invention.

FIG. 4B illustrates another embodiment of the LFSR circuit 230b which can interleave output values from the DUT 16 using OR gates 320-322. By interleaving the output values (e.g., over output lines 330-332) into the LFSR 230b, the effective “randomness” of the result is increased. This also increases error detection because an error on the output lines 330-332 will generate an improper input test pattern which will likely lead to another departure from the expected result on the output, etc. This increases the likelihood that the error is detected by the verification circuitry 240 (FIG. 2, FIG. 3). The output lines 330-332 originate from the output of the DUT 16. The value of line 330 is ORed into the output of the first stage 310. The value of line 331 is ORed into the output of the second stage 311. The value of line 332 is ORed into the output of the third stage 312. It is appreciated that any number of stages can be used in accordance with this embodiment of the present invention.

### ATPG Computer System Platform 12

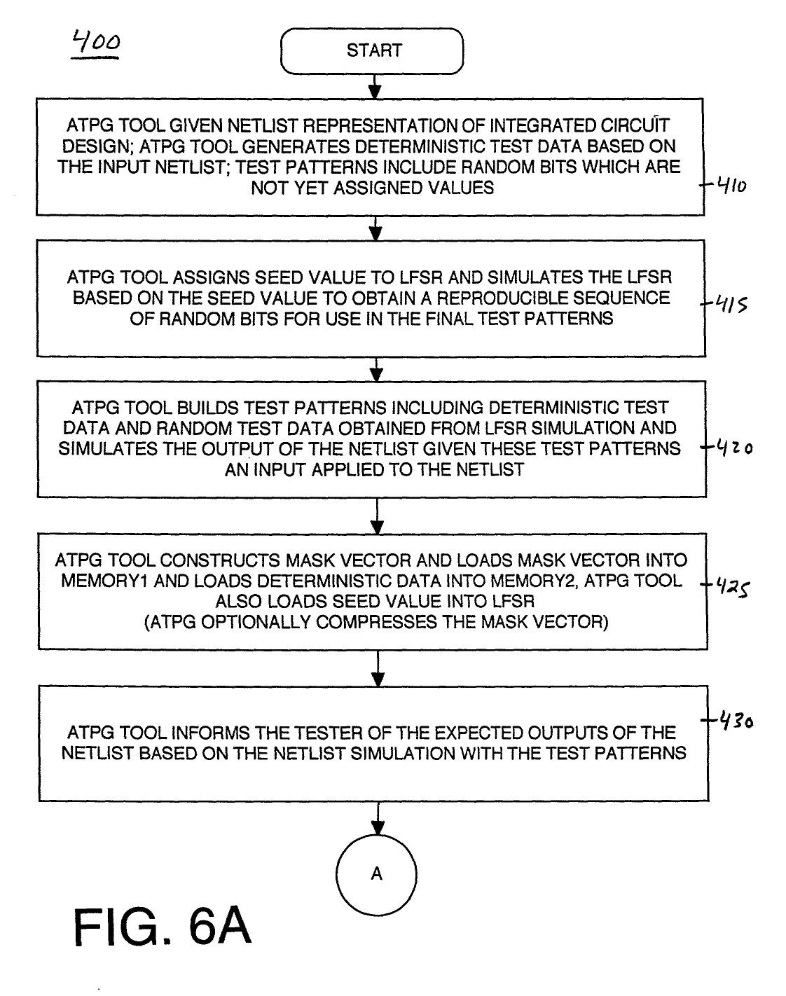

Referring to FIG. 5, a computer-implemented ATPG system 12 is illustrated, also called a computed aided design (CAD) tool. Within the following discussions of the present invention, certain processes and steps are discussed that are realized, in one embodiment, as a series of instructions (e.g., software program) that reside within computer readable memory units of system 12 and executed by processors of system 12. When executed, the instructions cause computer system 12 to perform specific actions and exhibit specific behavior which is described in detail to follow.

In general, the ATPG system 12 of the present invention includes an address/data bus 100 for communicating information, one or more central processor(s) 101 coupled with bus 100 for processing information and instructions, a computer readable volatile memory unit 102 (e.g., random access memory, static RAM, dynamic RAM, etc.) coupled with bus 100 for storing information and instructions for the central processor(s) 101, a computer readable non-volatile memory unit 103 (e.g., read only memory, programmable ROM, flash memory, EPROM, EEPROM, etc.) coupled with bus 100 for storing static information and instructions for processor(s) 101. System 12 can optionally include a mass storage computer readable data storage device 104, such as a magnetic or optical disk and disk drive coupled with bus 100 for storing information and instructions. Optionally, system 12 can also include a display device 105 coupled to bus 100 for displaying information to the computer user, an alphanumeric input device 106 including alphanumeric and function keys coupled to bus 100 for communicating information and command selections to central processor(s) 101, a cursor control device 107 coupled to bus for communicating user input information and command selections to the central processor(s) 101, and a signal input/output device 108 coupled to the bus 100 for communicating messages, command selections, data, etc., to and from processor(s) 101.

Program instructions executed by the ATPG system can be stored in RAM 102, ROM 103, or the storage device 104 and, when executed in a group, can be referred to as logic blocks or procedures. It is appreciated that data produced at the various logic synthesis stages of the present invention, including representations of the different levels of abstraction of the integrated circuit design, can also be stored in RAM 102, ROM 103, or the storage device 104 as shown in FIG. 1.

The display device 105 of FIG. 5 utilized with the computer system 12 of the present invention may be a liquid crystal device, cathode ray tube, or other display device suitable for creating graphic images and alphanumeric characters recognizable to the user. The cursor control device 107 allows the computer user to signal dynamically the two dimensional movement of a visible pointer on a display screen of the display device 105. Many implementations of the cursor control device are known in the art including a trackball, mouse, joystick, or special keys on the alphanumeric input device 105 capable of signaling movement of a given direction or manner of displacement.

### Process Flow of the Present Invention

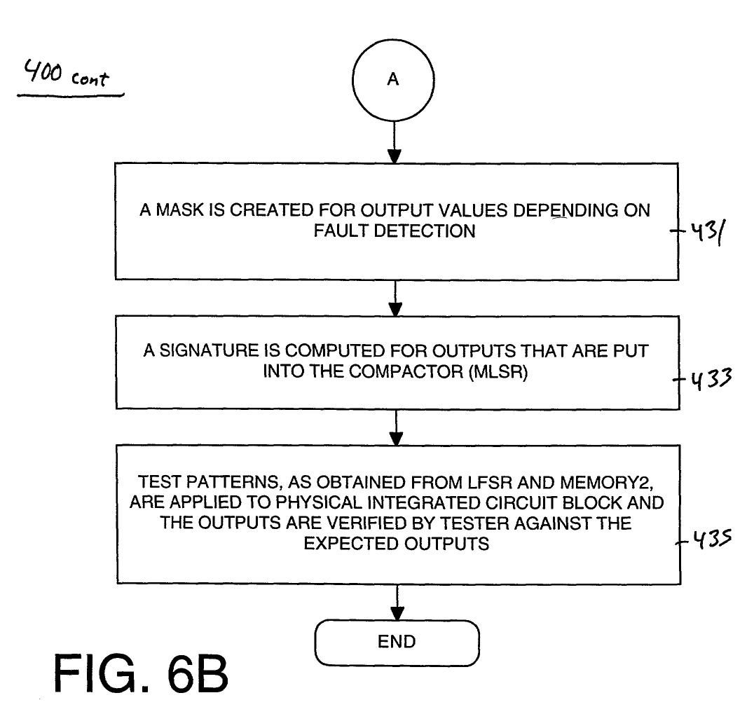

FIG. 6A and FIG. 6B illustrate a process 400 that can be used in accordance with embodiments of the present invention. At step 410 of FIG. 6A, the ATPG tool 12 is given a netlist representing the design of a DUT. The ATPG tool examines the netlist and using well known procedures and processes generates a set of deterministic test data for the netlist (D bits). The test patterns include positions for random bits (R bits) which are as of yet not assigned. The sequence positions of the deterministic bits with respect to the random bits are recorded.

At step 415, the ATPG tool assigns a seed value to a design of the LFSR and simulates it output based on the seed value and records this reproducible sequence of pseudo random bits. At step 420, the ATPG tool builds the final test patterns by adding the deterministic data to the sequence of pseudo random bits that were simulated from the LFSR. The proper sequence of bits is maintained. At step 420, the ATPG tool also simulates the operation of the netlist upon application of the complete test vectors thereto. The results of the netlist are recorded as expected results. Any number of well known methods and procedures can be used to perform this simulation process.

At step 425 of FIG. 6A, the ATPG tool uses the sequence positions of the deterministic bits with respect to the random bits in order to generate the mask vector (R+D bits). The mask vector is loaded into memory1 of the tester. Optionally, the mask vector is first compressed and then loaded into memory1. The D bits of deterministic data are loaded into memory2. The seed value is then loaded into the LFSR (that can be located on the tester or in the DUT). At step 430, the ATPG tool then loads the expected results from simulation into the verification logic of the tester.

At step 431 of FIG. 6B, a mask is created for output values depending on the fault detection. At step 433, a signature is computed for outputs that are put into the compactor (MLSR).

At step 435 of FIG. 6B, the tester then uses the generated test patterns to perform a test on the DUT to determine if any faults exist therein. The test patterns are generated by the select circuit selecting deterministic bits from memory2 and random bits from the LFSR under control of the mask vector from memory1. The test patterns are applied to the DUT logic and the actual results are scanned out and loaded back into the tester for verification against the expected results. Step 435 is repeated for each DUT of like kind that needs to be tested. It is appreciated that the specified test patterns cannot be generated without the LFSR seed value. Therefore, the seed value can be used as an encryption key. As an encryption key, it can be hidden in the DUT itself or it can be supplied only to authorized testers.

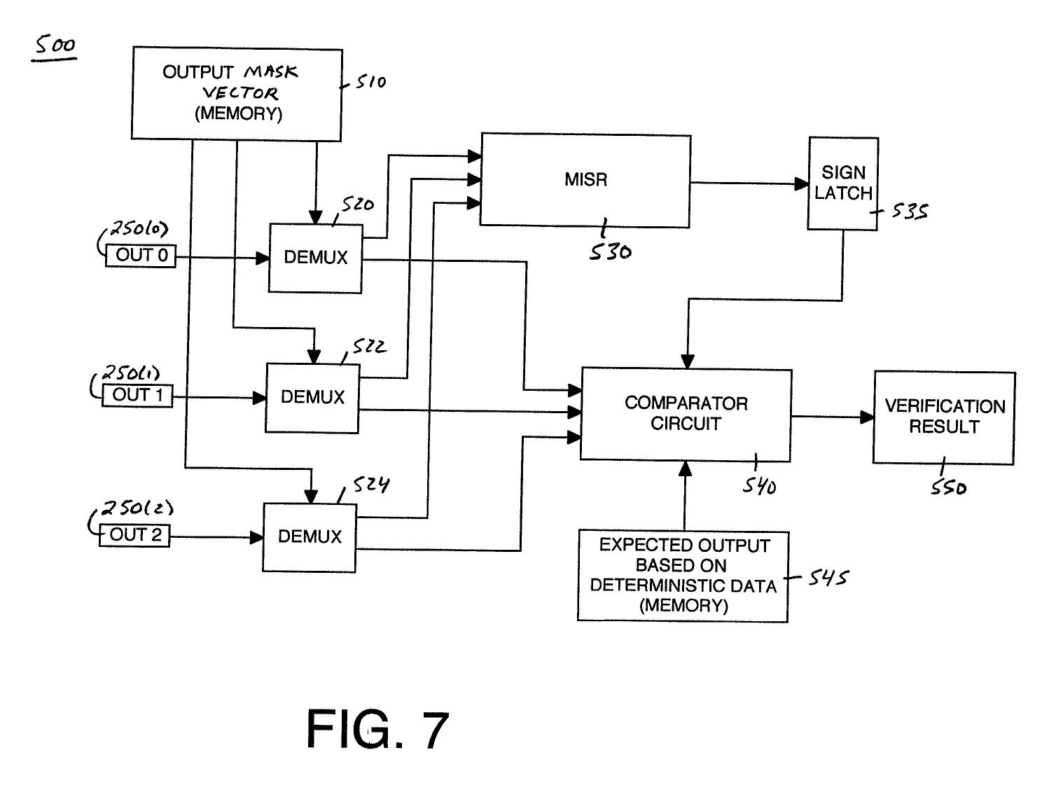

FIG. 7 illustrates that techniques of the present invention can also be used to reduce the memory required to store expected output values from the DUT that are used during verification. System 500 can be implemented within tester 14, e.g., within verifier 240. The expected outputs of the DUT contain portions that are generated based on deterministic input bits (of the test pattern) and portions that are generated based on random input bits (of the test pattern). In this example, a multiple input signature register, MISR 530, can be used as a compressed data repository for the portions of the expected output that are generated based on random input bits. The structure of a MISR is well known. By using the MISR 530, this embodiment of the present invention need only store the expected outputs that are associated with the deterministic input bits, e.g., the deterministic outputs.

FIG. 7 illustrates three exemplary bits (0-2) of bus 250 which represents the outputs of the DUT 16. Each of the output bits 250(0)-250(2) are coupled to an input of a respective demultiplexer circuit of circuits 520, 522 and 524. The demultiplexers are each coupled to a separate select line that originates from an output mask vector 510. The demultiplexers can supply the either the MISR 530 or a comparator circuit 540. The comparator circuit 540 is coupled to receive the expected outputs that correspond to the deterministic input bits from memory 545. The output mask vector 510 is generated during ATPG simulation and it contains a bit for each output bit generated by the DUT. If the corresponding output bit is generated by a random input bit, then its mask bit is “0.” This causes the demultiplexer to forward the output bit to the MISR 530. In contrast, if the corresponding output bit is generated by a deterministic input bit, then its mask bit is “1.” This causes the demultiplexer to forward the output bit to the comparator 540. It is appreciated that the logical assignments can also be reversed.

All deterministic output bits are compared against their expected values by comparator 545. If an error or mismatch is detected then flag 550 is set. All output bits generated by random input bits are supplied to the MISR and the MISR generates a signature value after each bit. The MISR generates a result signature after all the random bits have been received. The result signature is then latched into signature latch 535. The ATPG tool can simulate the expected resultant signature, and this value is stored in memory 545. Therefore, circuit 540 can compare the expected final signature against the actual final signature as stored in signature latch 535. If there are any errors or mismatches, the error flag 550 is set. If the error flag 550 is ever set, then verification for the DUT fails.

An advantage of the system 500 of FIG. 7 is that only the deterministic output need be stored in memory 545 thereby further reducing the memory, and cost, associated with tester 14. Even though an output mask vector of memory 510 needs to be stored, its regular pattern lends itself to compression, much like the mask vector of memory1 210 (FIG. 2). If the output mask pattern is optionally compressed, then a decompressor is required between the memory 510 and the demultiplexers.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order best to explain the principles of the invention and its practical application, thereby to enable others skilled in the art best to utilize the invention and various embodiments with various modifications as are suited to the particular use contemplated. It is intended that the scope of the invention be defined by the Claims appended hereto and their equivalents.

What is claimed is:

1. An integrated circuit tester apparatus comprising
a first memory for storing therein a mask vector for characterizing corresponding test vector data, said mask vector comprising a plurality of bit positions wherein a first bit value indicates that said corresponding test vector data is deterministic and wherein a second bit value indicates that said corresponding test vector data is pseudo random;
a second memory for storing therein deterministic test vector data;
a random number generator for generating a reproducible sequence of pseudo random bits based on a seed number; and
a selector circuit for generating a test vector for application to an integrated circuit, said selector circuit for selecting bits as between said random number generator and said second memory based on said mask vector, said selector circuit having an output for coupling to said integrated circuit.

2. An integrated circuit tester apparatus as described in claim 1 wherein said selector circuit is a multiplexer and wherein said multiplexer has a first data input coupled to said random number generator, a second data input coupled to said second memory, and a selector input coupled to said first memory, said multiplexer for passing through to said output a bit value of said first data input provided said selector input receives a first bit value and for passing through to said output a bit value of said second data input provided said selector input receives a second bit value.

3. An integrated circuit tester apparatus as described in claim 1 wherein said random number generator is a linear feedback shift register (LFSR).

4. An integrated circuit tester apparatus as described in claim 1 wherein said mask vector is data compressed.

5. An integrated circuit test apparatus as described in claim 4 and further comprising a decompressor coupled between said first memory and said selector circuit.

6. An integrated circuit tester apparatus as described in claim 1 wherein said deterministic test vector data is generated by an automatic test pattern generator (ATPG) process and downloaded into said second memory.

7. In integrated circuit testing system comprising:
a) an integrated circuit tester comprising:
a1) a first memory for storing therein a mask vector for characterizing corresponding test vector data, said mask vector comprising a plurality of bit positions wherein a first bit value indicates that said corresponding test vector data is deterministic and wherein a second bit value indicates that said corresponding test vector data is pseudo random; and
a2) a second memory for storing therein deterministic test vector data, said first and second memory coupled to a port;
b) an integrated circuit device under test (DUT) comprising:
b1) a circuit block to be tested;
b2) a random number generator for generating a reproducible sequence of pseudo random bits based on a seed number; and
b3) a selector circuit coupled to said port and for generating a test vector for application to said circuit block, said selector circuit for selecting bits as between said random number generator and said second memory based on said mask vector, said selector circuit having an output coupled to said circuit block.

8. An integrated circuit testing system as described in claim 7 wherein said selector circuit is a multiplexer and wherein said multiplexer has a first data input coupled to said random number generator, a second data input coupled to said second memory, and a selector input coupled to said first memory, said multiplexer for passing through to said output a bit value of said first data input provided said selector input receives a first bit value and for passing through to said output a bit value of said second data input provided said selector input receives a second bit value.

9. An integrated circuit testing system as described in claim 7 wherein said random number generator is a linear feedback shift register (LFSR).

10. An integrated circuit testing system as described in claim 7 wherein an output of said circuit block is coupled to an input of one stage of said LFSR.

11. An integrated circuit testing system as described in claim 7 wherein said mask vector is data compressed.

12. An integrated circuit testing system as described in claim 11 and further comprising a decompressor coupled between said first memory and said selector circuit.

13. An integrated circuit testing system as described in claim 7 wherein said deterministic test vector data is generated by an automatic test pattern generator (ATPG) process and downloaded into said second memory.

14. A method for testing an integrated circuit comprising the steps of:
a) retrieving a mask vector from a first memory, said mask vector for characterizing corresponding test vector data, said mask vector comprising a plurality of bit positions wherein a first bit value indicates that said corresponding test vector data is deterministic and wherein a second bit value indicates that said corresponding test vector data is pseudo random;
b) retrieving deterministic test vector data from a second memory;
c) initializing a random number generator with a seed number and thereafter generating a reproducible sequence of pseudo random bits based on said seed number; and
d) generating an output test vector for application to a circuit block of said integrated circuit, said step d) comprising the step of selecting bits as between said random number generator and said second memory based on said mask vector.

15. A method as described in claim 14 further comprising the steps of:
e) applying said output test vector to said circuit block;
f) obtaining an output generated by said circuit block in response to said output test vector;
g) verifying said circuit block by comparing said output generated by said circuit block to a reference output.

16. A method as described in claim 14 wherein said random number generator is a linear feedback shift register (LFSR).

17. A method as described in claim 14 further comprising the steps of:
applying said output test vector to said circuit block;
obtaining an output generated by said circuit block in response to said output test vector;
supplying said output generated by said circuit block to an input of a stage of said LFSR.

18. A method as described in claim 14 wherein said mask vector is data compressed on said first memory and wherein said step a) comprises the steps of:
a1) reading said mask data from said first memory; and
a2) decompressing said mask vector data.

19. A method as described in claim 14 wherein said deterministic test vector data is generated by an automatic test pattern generator (ATPG) process and downloaded into said second memory.

20. A method as described in claim 14 wherein said steps c) and d) are performed within said integrated circuit.
